(19) United States
(12) Patent Application Publication
(10) Pub. No.: US 2007/0023836 A1
(43) Pub. Date: Feb. 1, 2007

(54) Semiconductor device

(75) Inventor: Noriyuki Miura, Kanagawa (JP)

Correspondence Address: RABIN & Berdo, PC, 1101 14TH STREET, NW, SUITE 500, WASHINGTON, DC, 20005, US

(73) Assignee: OKI ELECTRIC INDUSTRY LTD.

(21) Appl. No.: 11/492,879

(22) Filed: Jul. 26, 2006

(30) Foreign Application Priority Data
Jul. 26, 2005 (JP) 2005-216210

(51) Int. Cl. H01L 27/12

(52) U.S. Cl. 257/347

(57) ABSTRACT

The present invention provides an MOSFET having a semiconductor substrate, an insulating layer provided on the semiconductor substrate, and an SOI layer provided on the insulating layer. A source region and a drain region are provided in the SOI layer. A non-doped region is provided at a position interposed between the source region and the drain region in the SOI layer. A gate electrode is provided over the SOI layer through a gate insulating film interposed therebetween. The drain region is provided at a position offset from the gate electrode, the source region is provided at a position where it overlaps with the gate electrode, and the offset length of drain region ranges from over 10 nm to under 75 nm.

### BACKGROUND OF THE INVENTION

The present invention relates to a semiconductor device, and particularly to a device structure of an MOSFET (Metal-Oxide-Semiconductor Field Effect Transistor) using an SOI (Silicon On Insulator) substrate.

In an MOSFET (which might be also called “SOI-MOSFET” in the following description) formed in an SOI substrate, a so-called short channel effect in which as a gate length becomes shorter with the miniaturization of each 2 elemental device, a threshold voltage (Vth) falls, takes place. Since the short channel effect yields the deterioration of a variation in threshold voltage, it is important to suppress the short channel effect. It has been known that making an SOI layer thinner is effective in suppressing the short channel effect (refer to, for example, a non-patent document 1 (N. Kistler et al., Solid State Electronics, vol. 39, No. 4, pp. 445-454 (1996)).

A structure of a generally-used conventional SOI-MOSFET will be explained referring to FIG. 10. A channel region 142 is provided in an SOI layer 140 of an SOI substrate 110 in which a buried oxide film layer 130 and the SOI layer 140 are sequentially laminated over a silicon substrate 120. A source region 144 and a drain region 146 are provided, as n-type impurity diffusion regions, in regions which interpose a channel region 142 lying in the SOI layer 140 therebetween.

A gate electrode 160 is formed on the upper side of the SOI layer 140 with a gate oxide film 150 in between. The source region 144 and the drain region 146 are provided at positions where they overlap with the gate electrode 160.

A description will be made of suppression of a short channel effect by making the thickness T_{SOI} of the SOI layer 140 thinner referring to FIG. 11. FIG. 11 is a characteristic diagram showing the relationship between threshold voltage roll-off (mV) and a gate length L_{g} (μm) in the conventional SOI-MOSFET described with reference to FIG. 10 and shows where the thickness of the SOI layer is 46 nm (indicated by signs Δ), 95 nm (indicated by signs) and 142 nm (indicated by signs ◯). In FIG. 11, the horizontal axis indicates the gate length L_{g} (μm), and the vertical axis indicates the threshold voltage roll-off (mV), respectively. Here, the threshold voltage roll-off indicates a difference between a reference voltage and a threshold voltage at the gate length L_{g} corresponding to each value different from 10 μm with a threshold voltage Vth at the gate length L_{g} of 10 μm being defined as the reference voltage.

It can be understood that as is apparent from the characteristic diagram of FIG. 11, the value of the threshold voltage roll-off becomes large as the gate length L_{g} becomes shorter, whereas as the thickness T_{SOI} of the SOI layer 140 becomes thinner, the value of the threshold voltage roll-off at the time that the gate length L_{g} becomes short, gets smaller. This makes it apparent that thinning the thickness T_{SOI} of the SOI layer 140 is effective in suppressing the short channel effect. A problem, however, arises in that the breakdown voltage of the MOSFET is reduced when the thickness T_{SOI} of the SOI layer 140 is made thin to suppress the short channel effect. It is undesirable to reduce the breakdown voltage of the MOSFET in terms of its device characteristic. It is proposed to set a gate electrode and a drain region to an offset structure with a view toward preventing the reduction in breakdown voltage (refer to, for example, a patent document 1 (Japanese Unexamined Patent Publication No. Sho 64(1989)-89464 or 2 (Japanese Unexamined Patent Publication Hei 7(1995)-183520)).

In the case of devices whose standby power consumption is desired to be lower, a semiconductor device in which a reduction in off-leak current Ioff has priority over an increase in its operating speed, is used as in a semiconductor device used for a portable terminal. In such a transistor (wherein Ioff<1×10⁻¹¹ A/m and threshold voltage: 0.4V or so) that the off-leak current is set low, the above thinning of the SOI layer 140 for suppressing the short channel effect yields the following problems.

A description will be made here of, as an example, a fully-depleted SOI-MOSFET in which part of a channel region 142 in an SOI layer 140 is fully depleted. In the fully-depleted SOI-MOSFET, the thickness T_{SOI} of the SOI layer 140 is generally formed to about 50 nm or smaller. The threshold voltage Vth (V) can be expressed in the following equation (1) using a potential φF (V), an elementary electric charge q (C), a flatband voltage Vfb (V), an impurity concentration (hereinafter also called “body concentration”) Na (cm³) of the channel region, the thickness T_{SOI} (nm) of the SOI layer 140, and a gate oxide film capacitance Cox (F):
Vth=Vfb+φF+q×Na×T_{SOI}/Cox (1)

Incidentally, the potential φF (V) indicates a value which depends on the body concentration, i.e., the impurity concentration of the channel region and becomes small with an increase in the body concentration. When the body concentration is approximately zero, the potential φF (V) is 0.56V or so. When the body concentration Na is approximately zero, q×Na×T_{SOI}/Cox also reaches approximately zero.

The flatband voltage Vfb (V) can be expressed in the following equation (2) using a gate electrode work function Wm, a silicon work function Ws, an interface charge density Qox, and a gate oxide film capacitance Cox (F):
Vfb=Wm−Ws−Qox/Cox (2)

In the case of an N type MOSFET (also called “SOI-NMOS”) formed on an SOI substrate, n⁺ polysilicon is used as the gate electrode 160. At this time, the gate electrode work function Wm is 4.15V or so. Further, the silicon work function Ws is about 4.7V. The interface charge density Qox is given from the product of a fixed charge amount of 4×10¹²/cm² per unit area, and an elementary electric charge of 1.6×10⁻¹⁹ C. Cox indicates the electrostatic capacitance of the gate oxide film 150. When the thickness Tox of the gate oxide film 150 is 50 nm, its electrostatic capacitance is 1.73×10⁻⁶ F/cm² or so. Thus, since Qox/Cox becomes Qox/Cox=4×10^{12×1.6×10}⁻¹⁹/1.73×10⁻⁶=0.37V, Vfb results in Vfb=4.15−4.7−0.37=−0.92V. As a result, the threshold voltage Vth reaches Vth=−0.92V+0.56V=−0.36V. This value is a value obtained when the body concentration Na is set to approximately zero. When the threshold voltage Vth is adjusted to 0.4V or so by introducing an impurity into the channel region 142, the body concentration should be set to 1×10¹⁸ cm⁻³ or higher.

FIG. 12 is a characteristic diagram showing the relationship between the gate length L_{g} of an SOI-NMOS having the conventional structure and its threshold voltage Vth. In FIG. 12, the horizontal axis indicates the gate length L_{g} (μm), and the vertical axis indicates the threshold voltage (V), respectively. A curve I indicated by a one-dot chain line shows a case in which no impurity is introduced into the channel region 142, and a curve II indicated by a solid line shows a case in which a p-type impurity is introduced into the channel region 142 and the body concentration Na is set to 1×10¹⁸ cm⁻³ or so. As shown in FIG. 12, the threshold voltage Vth is adjusted to 0.4V or so by setting the body concentration Na to 1×10¹⁸ cm⁻³ or so.

FIG. 13 is a characteristic diagram showing the relationship between a lateral profile of an SOI-NMOS and its impurity concentration where the body concentration Na is set to 1×10¹⁸ cm⁻³ or higher. The horizontal axis indicates the lateral profile (μm) of the SOI-NMOS, and the vertical axis indicates the impurity concentration (cm⁻³), respectively. A curve I indicated by a solid line indicates the concentration of boron (B) corresponding to a p-type impurity, which is introduced into the channel region 142. A curve II indicates by a one-dot chain line indicates the concentration of arsenic (As) corresponding to an n-type impurity, which is introduced into its corresponding source and drain regions 144 and 146. A curve III indicated by a broken line indicates a carrier concentration. The concentration of the p-type impurity at the channel region 142, i.e., the body concentration Na becomes high like 2×10¹⁸ cm⁻³ or so as shown in FIG. 13.

Thus, when the body concentration Na exceeds 1×10¹⁸ cm⁻³, a reduction in the mobility (electron mobility in the case of an NMOS) of carriers presents a problem. The reduction in the mobility thereof leads to a reduction in the drive current of a transistor.

FIG. 14 is a characteristic diagram for describing the relationship between the electron mobility and the vertical effective electric field. Each curve is also called “a mobility universal curve”. In FIG. 14, the horizontal axis indicates the vertical effective electric field (mV/cm), and the vertical axis indicates the electron mobility (cm²/(V·s)), respectively. The curves I through V respectively indicate the cases where the body concentration Na (unit: cm⁻³) is I: 3×10¹⁷, II: 1.3×10¹⁸, III: 1.8×10¹⁸, IV: 2.5×10¹⁸, and V: 3.3×10¹⁸. The electron mobility becomes smaller as the body concentration Na increases. The value of the vertical effective electric field indicated by broken-line arrow is equivalent to the case where 1.0V is applied as a gate voltage Vg and a drain voltage Vd. Thus, the electron mobility is reduced greatly as the body concentration Na becomes higher, so that the drive current of the transistor, i.e., its drive power is reduced.

In order to solve the problem that the transistor drive power is reduced due to the introduction of the impurity, a method for changing a gate electrode material without introducing the impurity into the channel region 142 of the SOI layer 140 to change the gate electrode work function Wm, thereby increasing the threshold voltage Vth has been attempted (refer to, for example, a patent document 3 (Japanese Unexamined Patent Publication No. 2004-146550)).

An example using p⁺ polysilicon as a gate electrode has been disclosed in the patent document 3. Using the p⁺ polysilicon as the gate electrode, the gate electrode work function Wm becomes 5.27V or so. A flatband voltage Vfb at the time that no impurity is introduced into the channel region, results in Vfb=5.27V−4.7V−0.37V=0.20V from the equation (2). Thus, the threshold voltage Vth reaches Vth=Vfb+φF=0.20V+0.56V=0.76V from the equation (1).

However, the semiconductor device (hereinafter might be also called “Non-doped SOI”) disclosed in the patent document 3, wherein no impurity is introduced into the channel region of the SOI layer, is not capable of controlling the threshold voltage Vth by the impurity concentration of the channel region 142. Therefore, a problem arises in that the influence of a short channel effect becomes large. FIG. 15 is a characteristic diagram showing the dependence of a threshold voltage Vth on a gate length L_{g} where the thickness T_{SOI} of the SOI layer 140 is 35 nm and the thickness Tox of the gate oxide film 150 is 2 nm. In FIG. 15, the horizontal axis indicates the gate length L_{g} (μm), and the vertical axis indicates the threshold voltage Vth (V), respectively. As the gate length L_{g} (μm) becomes shorter, the threshold voltage Vth (V) is reduced.

In general, the short channel effect of the Non-doped SOI is suppressed by making the SOI layer 140 thinner.

A threshold voltage Vth and an S-factor (:subthreshold factor) at the time that the thickness T_{SOI} of the SOI layer is changed, will be explained referring to FIG. 16. FIG. 16 is a characteristic diagram for describing the dependence of a threshold voltage Vth and an S-factor on a gate length L_{g} at the time that T_{SOI} is changed. The horizontal axis indicates the gate length L_{g} (μm), and the vertical axis indicates the threshold voltage Vth (V) and S-factor (mV/decade). Here, the S-factor is a gate voltage difference at the time that the drain current is changed one digit. If the S-factor is small even though the threshold values are the same, the off-leak current can be reduced in an MOSFET. The threshold voltage Vth and the S-factor at the time that the thickness T_{SOI} of the SOI layer 140 is 20 nm, are respectively designated at signs A and a. The threshold voltage Vth and the S-factor at the time that the thickness T_{SOI} thereof is 15 nm, are respectively designated at signs B and b. The threshold voltage Vth and the S-factor at the time that the thickness T_{SOI} thereof is 10 nm, are respectively designated at signs C and c. The threshold voltage Vth and the S-factor at the time that the thickness T_{SOI} thereof is 5 nm, are respectively designated at signs D and d.

With the thinning of the thickness T_{SOI} of the SOI layer 140, the threshold voltage roll-off at the time that the gate length L_{g} is made short, is suppressed, and an increase in the S-factor is restrained. However, when the threshold voltage roll-off is suppressed by thinning the thickness T_{SOI} of the SOI, there is a need to set the thickness T_{SOI} of the SOI layer 140 to 10 nm or less, using 80 mV/decade as a guide for an S-factor at the time that the gate length L_{g} is 0.1 μm. Incidentally, 80 mV/decade set as the guide for the S-factor is a value attainable in an MOSFET (bulk MOS) formed in a silicon substrate.

A problem arises in that the dimensional level that the thickness T_{SOI} of the SOI layer 140 is 10 nm or less, is very thin for application to a practical mass-production process as an SOI-MOSFET, and a variation in the thickness T_{SOI} of the SOI layer 140 occurs. It is thus difficult to obtain a stable transistor characteristic under the dimensional level that the thickness T_{SOI} of the SOI layer 140 is 10 nm or less.

### SUMMARY OF THE INVENTION

The present invention has been made in terms of the foregoing problems. An object of the present invention is to provide an MOSFET formed in an SOI substrate, which is capable of avoiding the occurrence of a conventional reduction in transistor drive power due to the introduction of an impurity, and suppressing a short channel effect.

According to one aspect of the present invention, for attaining the above object, there is provided a semiconductor device which is an MOSFET including a semiconductor substrate, an insulating layer provided on the semiconductor substrate, and an SOI layer provided on the insulating layer. A source region and a drain region are provided in the SOI layer. A non-doped region is provided at a position interposed between the source and drain regions in the SOI layer. A gate electrode is provided over the SOI layer with a gate insulating film interposed therebetween. The drain region is provided at a position offset from the gate electrode, the source region is provided at a position where the source region overlaps with the gate electrode, and the offset length of drain region ranges from over 10 nm to under 75 nm.

According to another aspect of the present invention, for attaining the above object, there is provided a semiconductor device wherein each of drain and source regions is provided at a position offset from a gate electrode, and the offset lengths of drain and source regions preferably ranges from over 2 nm to under 20 nm.

According to an SOI-MOSFET showing a semiconductor device of the present invention, it has a drain offset structure in which a drain region is provided at a position offset from a gate electrode, and a source overlap structure in which a source region is provided at a position where it overlaps with the gate electrode. The offset length of drain region ranges from over 10 nm and under 75 nm. With such a configuration, a reduction in the drive power of a transistor due to the introduction of an impurity into a channel region can be avoided, and a short channel effect can be suppressed.

According to another semiconductor device of the present invention, it has a drain offset structure and a source offset structure in which a source region is provided at a position offset from a gate electrode. Further, the offset lengths of drain and source regions are set so as to range from over 2 nm to under 20 nm. It is therefore possible to avoid a reduction in the drive power of a transistor due to the introduction of an impurity into a channel region and suppress a short channel effect in a manner similar to the above.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a schematic diagram for describing a semiconductor device according to a first embodiment;

FIG. 2 is a characteristic diagram for describing the dependence of a threshold voltage of the semiconductor device according to the first embodiment on its gate length;

FIG. 3 is a characteristic diagram for describing the relationship between threshold voltage roll-off and a drain offset length;

FIG. 4 is a characteristic diagram for describing the relationship between a drain current and a drain offset length;

FIG. 5 is a schematic diagram for describing a semiconductor device according to a second embodiment;

FIG. 6 is a characteristic diagram for describing the dependence of a threshold voltage of the semiconductor device according to the second embodiment on its gate length;

FIG. 7 is a characteristic diagram for describing the relationship between threshold voltage roll-off and an offset length;

FIG. 8 is a characteristic diagram for describing the relationship between a drain current and an offset length;

FIG. 9 is a characteristic diagram for describing the relationship between a drive voltage and a drain current;

FIG. 10 is a schematic diagram for describing a conventional semiconductor device;

FIG. 11 is a characteristic diagram showing the relationship between threshold voltage roll-off of a conventional SOI-MOSFET and its gate length;

FIG. 12 is a characteristic diagram illustrating the relationship between a gate length of an SOI-NMOS having a conventional structure and its threshold voltage;

FIG. 13 is a characteristic diagram depicting a lateral profile of an SOI-NMOSFET and its impurity concentration;

FIG. 14 is a characteristic diagram illustrating the relationship between electron mobility and a vertical effective electric field;

FIG. 15 is a characteristic diagram showing the dependence of a threshold voltage on a gate length; and

FIG. 16 is a characteristic diagram for describing the dependence of a threshold voltage and an S-factor on a gate length.

### DETAILED DESCRIPTION OF THE PREFERRED EMBODIMENTS

Preferred embodiments of the present invention will hereinafter be described with reference to the accompanying drawings. However, the shape, size and physical relationship of each constituent element in the figures are merely approximate illustrations to enable an understanding of the present invention. While preferred configurational examples of the present invention are explained below, the material and numerical conditions of each constituent element, etc. are nothing more than mere preferred examples. Accordingly, the present invention is by no means limited to such embodiments as to be described below.

### First Preferred Embodiment

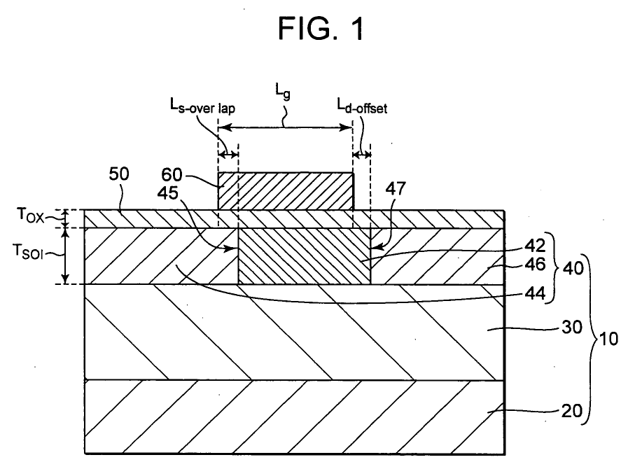

An MOSFET (Metal-Oxide-Semiconductor Field Effect Transistor) using an SOI (Silicon On Insulator) substrate will be explained as a semiconductor device according to a first embodiment with reference to FIG. 1. FIG. 1 is a schematic diagram for describing one example of a structure of the semiconductor device according to the first embodiment and shows it in the form of a cut area of its section.

The SOI substrate 10 may use an arbitrary suitable one known to date. In the SOI substrate 10, a buried oxide film (BOX) layer 30 used as an insulating layer and an SOI layer 40 are sequentially laminated over a silicon substrate 20 used as a semiconductor substrate.

A source region 44 and a drain region 46 are respectively provided in the SOI layer 40 as n-type impurity diffusion regions in discrete form. An impurity introduction-free non-doped region 42 is provided at a position interposed between the source and drain regions 44 and 46 in the SOI layer 40. The non-doped region 42 operates as a channel when the MOSFET is in an on state. Thus, the non-doped region 42 might be referred to as a channel region in the following description.

A gate electrode 60 is formed on the upper side of the SOI layer 40 with a gate oxide film 50 corresponding to a gate insulating film being interposed therebetween.

The semiconductor device according to the first embodiment has a drain offset structure. Here, the drain offset structure refers to a structure wherein the drain region 46 is provided at such a position that it has an offset with respect to the gate electrode 60, i.e., a structure wherein the gate electrode 60 is provided at a position spaced in a channel direction from a junction surface (drain junction surface) 47 at which the drain region 46 and the non-doped region 42 are bonded to each other. Even though a gate length L_{g} becomes short with the provision of the drain offset structure, an effective channel length is extended by a length corresponding to an offset length (drain offset length) L_{d-offset} of the drain region 46. When the effective channel length increases, a short channel effect is suppressed.

The semiconductor device according to the first embodiment also has a source overlap structure. Here, the source overlap structure refers to a structure wherein the source region 44 is provided at a position where it overlaps with the gate electrode 60, that is, a structure wherein a junction surface (source junction surface) 45 at which the source region 44 and the non-doped region 42 are bonded to each other, is located at the SOI layer 40 placed below the gate electrode 60. With the provision of the source overlap structure, a channel resistance is suppressed low and hence a drive current of a transistor becomes high.

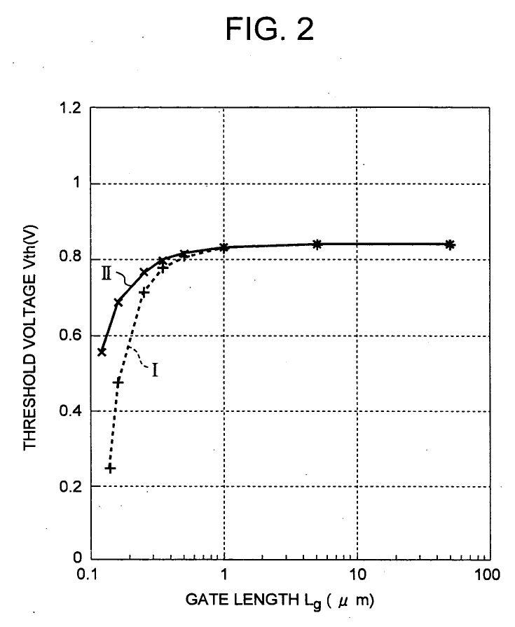

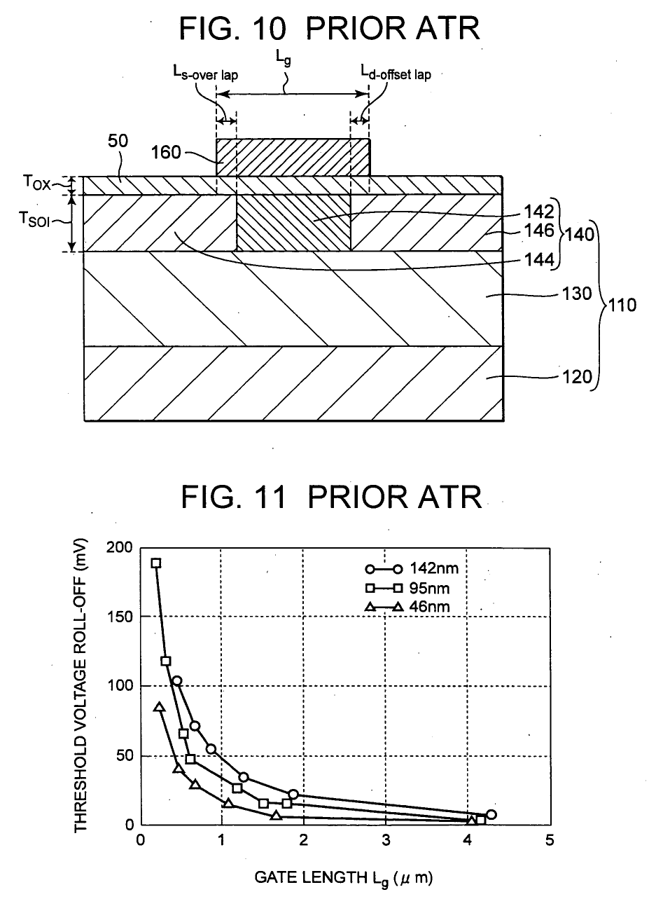

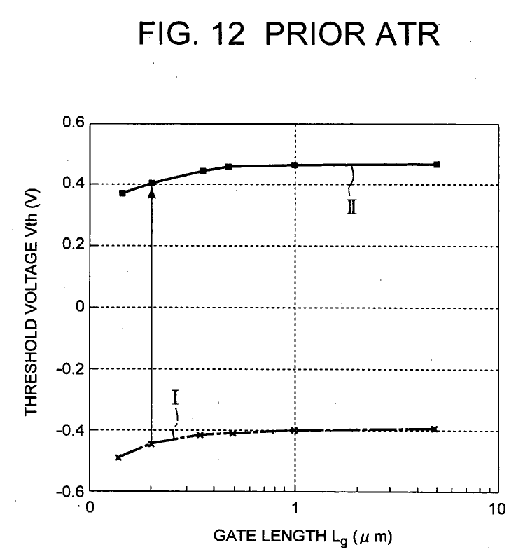

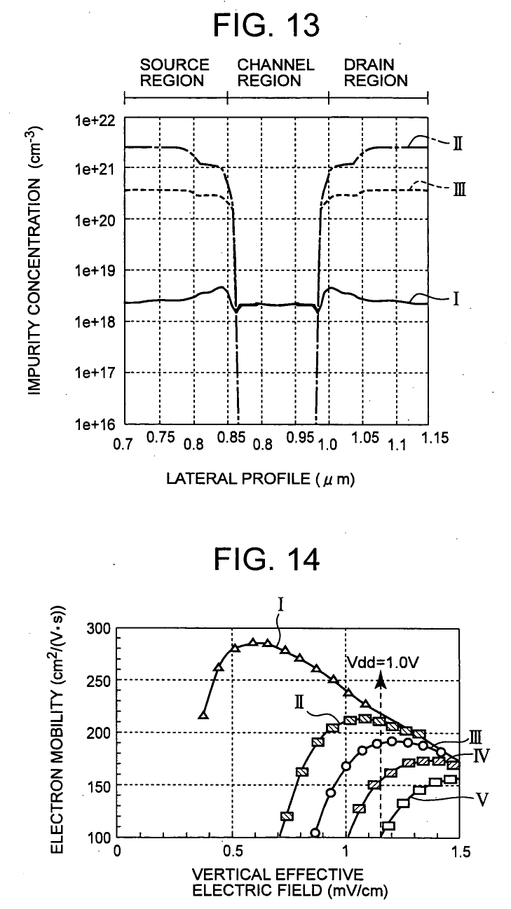

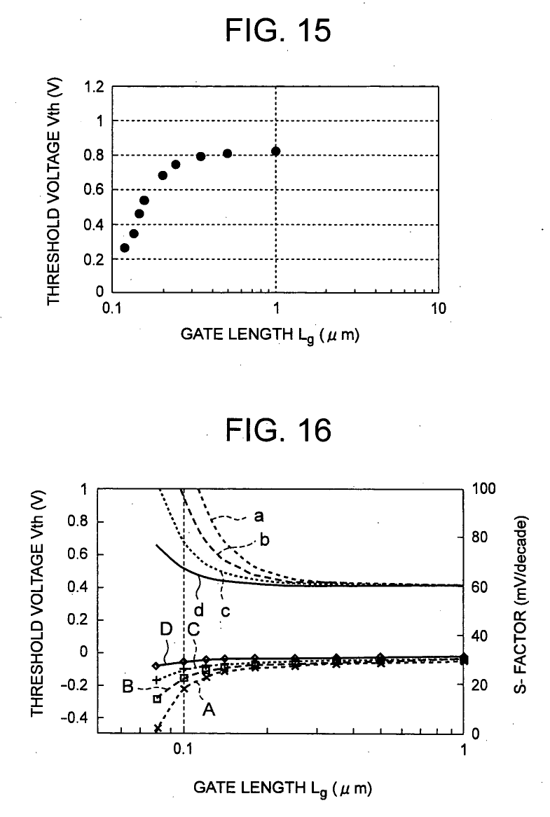

A description will be made of the dependence of threshold voltages of the semiconductor device according to the first embodiment and the conventional semiconductor device on their gate lengths with reference FIG. 2. FIG. 2 is a characteristic diagram for explaining the dependence of the threshold voltage of the semiconductor device according to the first embodiment on its gate length and shows a simulation result where the thickness T_{SOI} of the SOI layer 40 is set to 35 nm, the thickness T_{OX} of the gate oxide film 50 is set to 2.5 nm, and the gate electrode 60 is formed as p-type polysilicon. The dependence (see a curve I in the figure) of the threshold voltage Vth on the gate length L_{g} in the conventional semiconductor device described with reference to FIG. 10, and the dependence (see a curve II in the figure) of a threshold voltage Vth on a gate length L_{g} in the semiconductor device according to the first embodiment are shown in FIG. 2. The horizontal axis indicates the gate length L_{g} (μm), and the vertical axis indicates the threshold voltage Vth (V), respectively.

The semiconductor device according to the first embodiment has the drain offset structure and the source overlap structure. In the present semiconductor device, the drain offset length L_{d-offset} is set to 20 nm, and the overlapped length (source overlap length) Lₛ₋ₒᵥₑᵣₗₐₚ of the source region 44 is set to 20 nm. On the other hand, the conventional semiconductor device has the drain overlap structure and the source overlap structure and is configured such that the overlapped length (drain overlap length) L_{d-overlap} of the drain region 146 is set to 20 nm, and the source overlap length Lₛ₋ₒᵥₑᵣₗₐₚ is set to 20 nm. Here, the drain overlap structure refers to a structure wherein the drain region 146 is provided at a position where it overlaps with the gate electrode 160.

In the conventional semiconductor device having the drain overlap structure and the source overlap structure, there was a need to set the thickness T_{SOI} of the SOI layer 140 to 10 nm or less in order to suppress the short channel effect as explained with reference to FIG. 16. When the thickness T_{SOI} of the SOI layer 40 is set to 30 nm, a reduction in the threshold voltage Vth becomes pronounced with respect to the gate length L_{g} of 1 μm or less as indicated by the curve I of FIG. 2.

In the semiconductor device according to the first embodiment in contrast to this, it is understood that although a reduction in the threshold voltage Vth due to the short channel effect occurs in a region in which the gate length L_{g} is 1 μm or less, as indicated by the curve II of FIG. 2, the degree of its reduction is small as compared with the conventional semiconductor device (curve I) and the short channel effect is suppressed. That is, in the semiconductor device according to the first embodiment, the short channel effect is suppressed even though the thickness T_{SOI} of the SOI layer 40 is 35 nm or so.

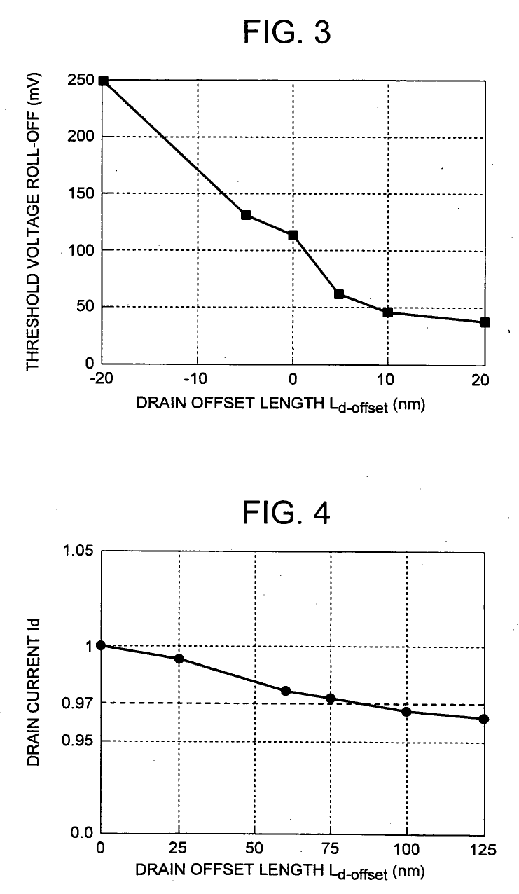

The relationship between threshold voltage roll-off and a drain offset length L_{d-offset} will be described with reference to FIG. 3. FIG. 3 is a characteristic diagram for explaining the relationship between the threshold voltage roll-off and the drain offset length L_{d-offset} and shows the result of simulation executed in consideration of a variation of 20 nm with 140 nm being centered as the gate length L_{g}. In FIG. 3, the horizontal axis indicates the drain offset length L_{d-offset} (nm), and the vertical axis indicates the threshold voltage roll-off (mV), respectively. When the drain offset length L_{d-offset} is increased as shown in FIG. 3, the threshold voltage roll-off is reduced. When the drain offset length L_{d-offset} is 0 nm or less, for example, the threshold voltage roll-off is larger than 100 mV. On the other hand, when the drain offset length L_{d-offset} is 10 nm or longer, the threshold voltage roll-off becomes smaller than 50 mV.

In FIG. 3, the drain offset length L_{d-offset} corresponds to the interval between an electrode end of the gate electrode 60 and the drain junction surface 47 as viewed in the channel direction and is assumed to be a positive value in the case of the drain offset structure. When the drain offset length L_{d-offset} is zero, it shows that the electrode end of the gate electrode 60 and the position of the drain junction surface 47 as viewed in the channel direction coincide with each other. When the drain offset length L_{d-offset} indicates a negative value, it shows that the drain overlap structure is taken and yields an overlap by the magnitude of its absolute value. That is, the drain offset length L_{d-offset} and the drain overlap length L_{d-overlap} are placed in such a relationship (L_{d-offset}=−L_{d-overlap}) that they are equal to each other in absolute value and opposite to each other in sign.

As described with reference to FIG. 2, the threshold voltage Vth becomes small due to the short channel effect when the gate length L_{g} is decreased. When the threshold voltage roll-off indicative of the degree of the reduction in the threshold voltage Vth is large, the magnitude of the threshold voltage Vth varies greatly when the gate length L_{g} varies. That is, the sensitivity of the threshold voltage Vth with respect to the variation in the gate length L_{g} becomes high. Thus, the variation in the gate length L_{g} leads to a reduction in yield. Particularly when the threshold voltage roll-off becomes larger than 50 mV, its tendency becomes greater. Thus, in order to prevent the reduction in yield due to the variation in the gate length L_{g}, the threshold voltage roll-off may preferably be set to within 50 mV and the drain offset length L_{d-offset} may suitably be set to 10 nm or larger.

A description will be made of the relationship between a drain current Id and a drain offset length L_{d-offset} with reference to FIG. 4. FIG. 4 is a characteristic diagram for explaining the relationship between the drain current Id and the drain offset length L_{d-offset} and shows the result of simulation done under a condition similar to FIG. 3. In FIG. 4, the horizontal axis indicates the drain offset length L_{d-offset} (nm), and the vertical axis indicates the ratio of the drain current Id to the value equivalent to 0 nm, of the drain offset length L_{d-offset}.

As shown in FIG. 4, the drain current Id corresponding to the drive current of the transistor is reduced as the drain offset length L_{d-offset} becomes long. When the drain offset length L_{d-offset} is 0 nm, the drain current Id is 1, whereas when the drain offset length L_{d-offset} is 75 nm, the drain current Id becomes 0.97 or so. Further, when the drain offset length L_{d-offset} exceeds 100 nm, the drain current Id becomes a value less than 0.97. There is a fear that when the drive current of the transistor is reduced, the response speed of a circuit constituted using the transistor is lowered so that a high-speed operation cannot be performed. Its tendency becomes great particularly when the reduction in the drive current is larger than 3%. Thus, in the semiconductor device according to the first embodiment, the drain offset length L_{d-offset} may preferably be set to 75 nm or less in such a manner that the reduction in the drive current, i.e., the drain current Id is suppressed to within 3%.

Incidentally, the semiconductor device according to the first embodiment can be manufactured using the arbitrary suitable SOI-MOSFET manufacturing method known to date. The setting of the drain offset length L_{d-offset} can be carried out by controlling a heat-treating time and the like upon annealing or heat treatment applied when the source region 44 and the drain region 46 are provided as the impurity diffusion regions.

As mentioned above, the semiconductor device according to the first embodiment has the drain offset structure and the source overlap structure, and the offset length of the drain region ranges from over 10 nm to under 75 nm. Constructing the semiconductor device in this way makes it possible to avoid the occurrence of the reduction in the drive power of the transistor due to the introduction of the impurity into the channel region and suppress the short channel effect.

### Second Preferred Embodiment

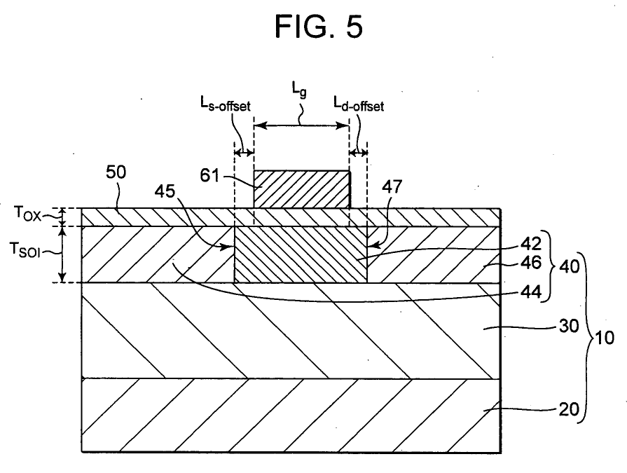

An MOSFET using an SOI substrate will be explained as a semiconductor device according to a second embodiment with reference to FIG. 5. FIG. 5 is a schematic diagram for explaining one example of a structure of the semiconductor device according to the second embodiment and shows it in the form of a cut area of its section.

The SOI substrate 10 may use an arbitrary suitable one known to date. In the SOI substrate 10, a buried oxide film (BOX) layer 30 used as an insulating layer and an SOI layer 40 are sequentially laminated over a silicon substrate 20 used as a semiconductor substrate.

A source region 44 and a drain region 46 are respectively provided in the SOI layer 40 as n-type impurity diffusion regions in discrete form. An impurity introduction-free non-doped region 42 is provided at a position interposed between the source and drain regions 44 and 46 in the SOI layer 40.

A gate electrode 61 is formed on the upper side of the SOI layer 40 with a gate oxide film 50 corresponding to a gate insulating film being interposed therebetween.

The semiconductor device according to the second embodiment has a drain offset structure. With the provision of the drain offset structure, an effective channel length is extended by a length corresponding to a drain offset length L_{d-offset} even though a gate length L_{g} becomes short. When the effective channel length is increased, a short channel effect is suppressed.

The semiconductor device according to the second embodiment has a source offset structure. Here, the source offset structure refers to a structure wherein the source region 44 is provided at such a position that it has an offset with respect to a gate electrode 61, i.e., a structure wherein the gate electrode 61 is provided at a position spaced away from a source junction surface 45. The semiconductor device according to the second embodiment has the source offset structure in addition to the drain offset structure. Therefore, as compared with the semiconductor device according to the first embodiment, an effective channel length is extended by a length corresponding to an offset length (source offset length) L_{s-offset} of the source region 44. Thus, the short channel effect is further suppressed.

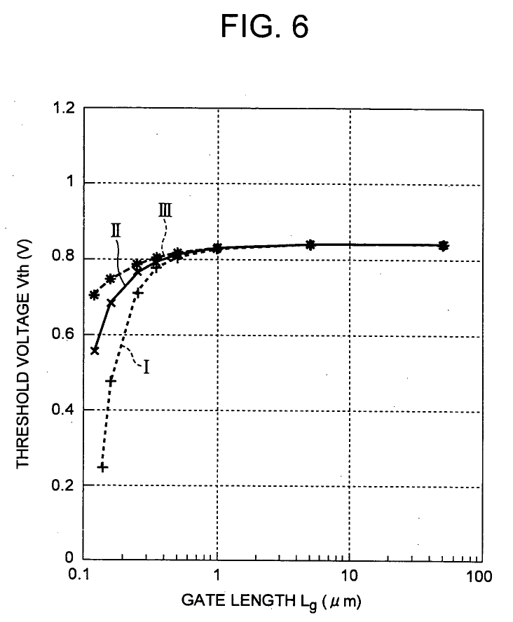

A description will be made of the dependence of threshold voltages of the semiconductor device according to the second embodiment and the conventional semiconductor device on their gate lengths with reference FIG. 6. FIG. 6 is a characteristic diagram for explaining the dependence of the threshold voltage of the semiconductor device according to the second embodiment on its gate length and shows a simulation result where the thickness T_{SOI} of the SOI layer 40, the thickness Tox of the gate oxide film 50 and the material of the gate electrode 61, and the like are set to conditions similar to those described with reference to FIG. 2. The dependence (see a curve III) on the gate length in the semiconductor device according to the second embodiment, and the dependence (see the curve I) on the gate length in the conventional semiconductor device described with reference to FIG. 2 and the dependence (see the curve II) on the gate length in the semiconductor device according to the first embodiment are shown in FIG. 6. The semiconductor device according to the second embodiment has the drain offset structure and the source offset structure. In the present semiconductor device, the drain offset length L_{d-offset} is set to 20 nm, and the source offset length L_{s-offset} is set to 20 nm.

In the conventional semiconductor device having the drain overlap structure and the source overlap structure, there was a need to set the thickness T_{SOI} of the SOI layer 140 to 10 nm or less in order to suppress the short channel effect as explained with reference to FIG. 16. That is, when the thickness T_{SOI} of the SOI layer 40 is set to 35 nm, a reduction in the threshold voltage Vth becomes pronounced in a region in which the gate length L_{g} is 1 μm or less.

In the semiconductor device according to the second embodiment in contrast to this, it is understood that although a reduction in the threshold voltage Vth due to the short channel effect occurs in the region in which the gate length L_{g} is 1 μm or less, as indicated by the curve III of FIG. 6, the degree of its reduction is small as compared with the conventional semiconductor device (curve I) and the short channel effect is suppressed. Further, the short channel effect is suppressed even as compared with the semiconductor device (curve II) according to the first embodiment.

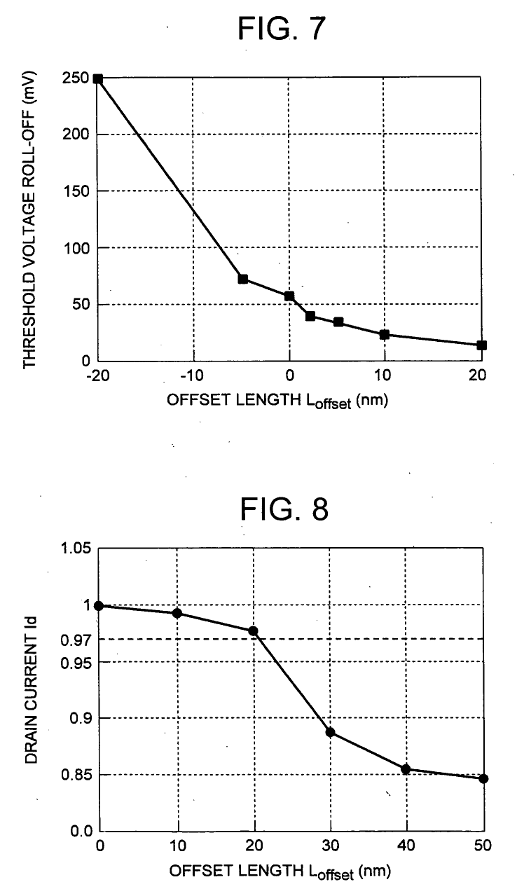

The dependence of threshold voltage roll-off on an offset length L_{offset} will be explained with reference to FIG. 7. FIG. 7 is a characteristic diagram for explaining the relationship between the threshold voltage roll-off and the offset length L_{offset} and shows the result of simulation executed in consideration of a variation of 20 nm with 140 nm being centered as the gate length L_{g}. In FIG. 7, the horizontal axis indicates the offset length L_{offset} (nm), and the vertical axis indicates the threshold voltage roll-off (mV), respectively.

Here, the drain offset length L_{d-offset} corresponds to the interval between an electrode end of the gate electrode 61 and a drain junction surface 47 as viewed in a channel direction and is assumed to be a positive value in the case of the drain offset structure. When the drain offset length L_{d-offset} is zero, it shows that the electrode end of the gate electrode 61 and the position of the drain junction surface 47 as viewed in the channel direction coincide with each other. When the drain offset length L_{d-offset} indicates a negative value, it shows that the drain overlap structure is taken and yields an overlap by the magnitude of its absolute value. That is, the drain offset length L_{d-offset} and the drain overlap length L_{d-overlap} are placed in such a relationship (L_{d-offset}=−L_{d-overlap}) that they are equal to each other in absolute value and opposite to each other in sign.

Similarly, the source offset length L_{s-offset} corresponds to the interval between the electrode end of the gate electrode 61 and the source junction surface 45 as viewed in the channel direction and is assumed to be a positive value in the case of the source offset structure. When the source offset length L_{s-offset} is zero, it shows that the electrode end of the gate electrode 61 and the position of the source junction surface 45 as viewed in the channel direction coincide with each other. When the source offset length L_{s-offset} indicates a negative value, it shows that the source overlap structure is taken and yields an overlap by the magnitude of its absolute value. That is, the source offset length L_{s-offset} and the source overlap length Lₛ₋ₒᵥₑᵣₗₐₚ are placed in such a relationship (L_{s-offset}=−Lₛ₋ₒᵥₑᵣₗₐₚ) that they are equal to each other in absolute value and opposite to each other in sign.

Incidentally, since the drain offset length L_{d-offset} and the source offset length L_{s-offset} are set equal to each other here, the drain offset length L_{d-offset} and the source offset length L_{s-offset} are generically called the offset length L_{offset}.

When the offset length L_{offset} is increased as shown in FIG. 7, the threshold voltage roll-off is reduced. When the offset length L_{offset} is 0 nm or less, the threshold voltage roll-off is larger than 50 mV. On the other hand, when the offset length L_{offset} is 2 nm or longer, the threshold voltage roll-off becomes smaller than 50 mV.

As described with reference to FIG. 6, the threshold voltage Vth becomes small due to the short channel effect when the gate length L_{g} is decreased. When the threshold voltage roll-off indicative of the degree of the reduction in the threshold voltage Vth is large, the magnitude of the threshold voltage Vth varies greatly when the gate length L_{g} varies. That is, the sensitivity of the threshold voltage Vth with respect to the variation in the gate length L_{g} becomes high. Thus, the variation in the gate length L_{g} leads to a reduction in yield. Particularly when the threshold voltage roll-off becomes larger than 50 mV, its tendency becomes great. Thus, in order to prevent the reduction in yield due to the variation in the gate length L_{g}, the threshold voltage roll-off may preferably be set to within 50 mV and the offset length L_{offset} may suitably be set to 2 nm or longer.

A description will be made of the relationship between a drain current Id and an offset length L_{offset} with reference to FIG. 8. FIG. 8 is a characteristic diagram for explaining the relationship between the drain current Id and the offset length L_{offset} and shows the result of simulation done under a condition similar to FIG. 7. In FIG. 8, the horizontal axis indicates the offset length L_{offset} (nm), and the vertical axis indicates the ratio of the drain current Id to the value equivalent to 0 nm, of the offset length L_{offset}.

As shown in FIG. 8, the drain current Id corresponding to the drive current of the transistor is reduced as the offset length L_{offset} becomes long. When the offset length L_{offset} is 0 nm, the drain current Id is 1, whereas when the offset length L_{offset} is 20 nm, the drain current Id becomes 0.97 or so. Further, when the offset length L_{offset} exceeds 30 nm, the drain current Id reaches a value less than 0.97. There is a fear that when the drive current of the transistor is reduced, the response speed of a circuit constituted using the transistor is lowered so that a high-speed operation cannot be performed. Its tendency becomes great particularly when the reduction in the drive current is larger than 3%. Thus, in the semiconductor device according to the second embodiment, the offset length L_{offset} may preferably be set to 20 nm or less in such a manner that the reduction in the drive current, i.e., the drain current Id is suppressed to within 3%.

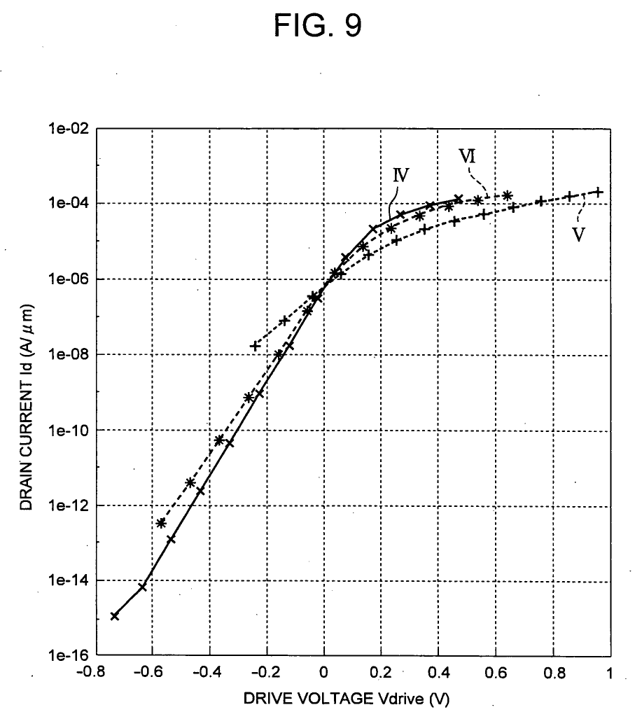

The relationship between a drive voltage Vdrive and a drain current Id will be explained with reference to FIG. 9. FIG. 9 is a characteristic diagram for explaining the relationship between the drive voltage Vdrive and the drain current Id and shows the result of simulation at the time that the gate length L_{g} is 140 nm, the thickness T_{SOI} of the SOI layer 40 is 35 nm, and a drain voltage Vd is 1.0V. In FIG. 9, the horizontal axis indicates the drive voltage Vdrive (V), and the vertical axis indicates the drain current Id (A/μm), respectively. Here, the drive voltage Vdrive indicates a difference between a gate voltage Vg and a threshold voltage Vth at the time that the drain voltage Vd is 1.0V. Further, the drain current Id (A/μm) is expressed as a current value per unit gate width. An S-factor is expressed in the inverse of a tilt of the drain current Id to the drive voltage Vdrive.

A curve IV in FIG. 9 indicates a drain current at the semiconductor device according to the second embodiment, having the drain offset structure and the source offset structure. A curve V indicates a drain current at an MOSFET in which no impurity is introduced into a channel region, i.e., a semiconductor device having a drain overlap structure and a source overlap structure (non-doped overlap structure). A curve VI indicates a drain current at an MOSFET in which a channel region is brought to a high concentration, i.e., a semiconductor device having a drain overlap structure and a source overlap structure (high-concentration body structure).

In the semiconductor device (curve IV) according to the second embodiment, the tilt of the drain current Id to the drive voltage Vdrive is large, i.e., the S-factor is small as compared with the semiconductor device (curve V) having the non-doped overlap structure.

In the semiconductor device (curve IV) according to the second embodiment as well, the tilt is large, that is, the S-factor is small even as compared with the semiconductor device (curve VI) having the high-concentration body structure. Further, since a body concentration is high in the semiconductor device having the high-concentration body structure, the drive power of the transistor is deteriorated as described with reference to FIG. 14, whereas since no impurity is implanted in the semiconductor device according to the second embodiment, the deterioration of the drive power due to the impurity introduced into the channel region does not occur.

Incidentally, although the present embodiment has explained, as an example, the case in which the drain offset length L_{d-offset} and the source offset length L_{s-offset} are equal to each other, they may be different from each other if they are provided within a range from over 2 nm to under 20 nm.

As described above, the semiconductor device according to the second embodiment has the drain offset structure and the source offset structure. Further, the offset lengths of drain and source regions range from over 2 nm to under 20 nm. In a manner similar to the semiconductor device according to the first embodiment, the semiconductor device according to the second embodiment is capable of avoiding the occurrence of the reduction in the drive power of the transistor due to the introduction of the impurity into the channel region and suppressing the short channel effect.

While the preferred forms of the present invention have been described, it is to be understood that modifications will be apparent to those skilled in the art without departing from the spirit of the invention. The scope of the invention is to be determined solely by the following claims.

What is claimed is:

1. A semiconductor device which is an MOSFET, said MOSFET including,
a semiconductor substrate;
an insulating layer provided over the semiconductor substrate;
an SOI layer provided over the insulating layer; a source region and a drain region provided in the SOI layer;
a non-doped region provided at a position interposed between the source and drain regions in the SOI layer; and
a gate electrode provided over the SOI layer through a gate insulating film interposed therebetween,
wherein the drain region is provided at a position offset from the gate electrode,
wherein the source region is provided at a position where the source region overlaps with the gate electrode, and
wherein the offset length of drain region ranges from over 10 nm to under 75 nm.

2. A semiconductor device which is an MOSFET, said MOSFET including,
a semiconductor substrate;
an insulating layer provided over the semiconductor substrate;
an SOI layer provided over the insulating layer;
a source region and a drain region provided in the SOI layer;
a non-doped region provided at a position interposed between the source and drain regions in the SOI layer; and
a gate electrode provided over the SOI layer through a gate insulating film interposed therebetween,
wherein each of the drain region and the source region is provided at a position offset from the gate electrode, and
wherein the offset lengths of drain and source regions range from over 2 nm to under 20 nm.
